(19) United States
(12) Patent Application Publication
(10) Pub. No.: US 2006/0083044 A1
(43) Pub. Date: Apr. 20, 2006

(54) MMC memory card with TSOP package

(76) Inventors: Chi Hong Chen, Chu-Dong Town (TW); Wen Chuan Chen, Chu-dong Town (TW); Kuo-Feng Peng, Chu-Dong Town (TW); Chia Jung Chang, Chu-Dong Town (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/963,523

(22) Filed: Oct. 14, 2004

(51) Int. Cl. G11C 5/02

(52) U.S. Cl. 365/52

(57) ABSTRACT

The MMC memory card with TSOP package includes a circuit board with a plurality of passive elements and ICs installed thereon and a plastic housing is covered over and enclosing the circuit board to form a memory card structure. At least one flash memory of the ICs is used with a TSOP package and the housing has a space to position the TSOP type flash memory such that said TSOP type flash memory is assembled with the housing and the total thickness of the assembly meets the requirement of the standard specification.

### FIELD OF THE INVENTION

The present invention relates to a “MMC memory card used with TSOP package” and, more particularly, to a MMC memory card suitable for using in digital cameras, handy computers etc. Due to the MMC memory card is a standard specification so the thickness of the MMC memory card is fixed. The present invention reduces the material cost of the flash memory and the manufacturer cost of the plastic housing, meanwhile, the present invention also reaches the goals of good assembled quality and efficiency under the limited conditions such as thickness.

### BACKGROUND OF THE INVENTION

Generally, the prior art MMC memory card is used in digital cameras, handy computers etc.

The assembly structure of the prior art MMC memory card mainly had a plurality of passive elements and various ICs 12 (generally, including flash memories, control chips) installed on the circuit board 11 in sequence, and then sealed the circuit board 11 by molding, gluing or sealing method to form the required printed circuit board, finally, covered a housing 13 (please refer to FIG. 1) over the printed circuit board to form a MMC memory card 10.

However, the prior art MMC memory card has the following drawbacks:

(1). Process is complex: the assembly process of the prior art memory card needs to use molding, gluing or sealing method to seal the printed circuit board and unpackage electric elements (such as passive elements, flash memories and control chips) thereon, therefore, the assembly process of the prior art memory card is more complex.

(2) The cost of the IC is higher: the prior art memory card uses the aforesaid assembly process, due to the thickness of the memory card needs to be limited to 1.4 mm, so the thickness of the IC adapted by the memory card is limited and causes to increase the cost of the IC, meanwhile increases the difficulty of the assembly process and the cost of the elements.

(3) The cost of the housing is higher: due to the aforesaid thickness limited, the thickness of the housing covering the printed circuit board is also limited, thus causing the difficulty of the assembly process and increasing the cost.

(4) The yield rate is lower: in order to assemble the unpackaged IC on the printed circuit board, damage to the unpackaged IC usually happens during the assembly process, thus also causing a lower yield rate.

### SUMMARY OF THE INVENTION

According to one aspect of the present invention, the present invention replaces the unpackaged flash memory by the TSOP (Thin Small Outline Package) type package flash memory. The TSOP flash memory has been packaged at the factory, so the transport, the convenience of the assembly are satisfied than the IC component used in the prior art memory card. Furthermore, the TSOP flash memories are mass produced, so the memory card producers buy them easier from the market and at a lower price. Due to the TSOP flash memories have popularly been used in the flash memory ICs, so the supply source can be found in various ways and can be mass-produced immediately so that the cost is decreased. The capacity of the TSOP type memory is also larger than the others packaged types of flash memory of the same size; thus can reduce the assembly cost of the present invention's MMC memory card and has a larger capacity. Due to the thickness of the MMC memory card including the printed circuit board with the IC mounted thereon is limited to 1.4 mm, the present invention uses a well-designed housing for example but not limited to a molded plastic housing with a window structure and cooperates with the TSOP type flash memory and SMT to form a memory card by mounting side-direction pins on the printed circuit board, thus can easy control the thickness of the memory card to 1.4 mm. Wherein, the molded plastic housing enables its top surface to align with the top surface of the flash memory, and only the top surface of the flash memory can be seen from the window so as to form the MMC memory card with the thickness limited to 1.4 mm. Further, a sticker can be stuck over the window to improve the shielding effect. Further, using multiple layers frame design or housing with extreme thickness can also control the thickness of the MMC memory card to 1.4 mm easily.

Furthermore, the TSOP type flash memory cooperated to the SMT design also uses thicker flash memory, cooperating with the well-designed housing to increase its capacity and increase the product value by using thicker memory card and capacity flash memory and with the same thickness, thus can reduce the fabrication cost and improve the competition of the product.

The present invention has the following advantages:

To reduce the flash memory's cost: due to the present invention using adapted housing to position the printed circuit board with thicker TSOP type flash memory that is mounted thereon, so that it can reduce the flash memory and the memory card's cost, and due to the TSOP type flash memory has sufficient supply sources, so the flash memory's cost can further be decreased.

The percent defective rate is lower: during the assembly process, due to the present invention uses the TSOP type flash memory that is already packaged in the factories, so it involves less risks to damage the packaged IC, and thus also increases the throughput.

### BRIEF DESCRIPTION OF THE DRAWINGS

FIG. 1 shows a sectional view of the prior art memory card;

FIG. 2 shows an exploded view of the memory card according to one embodiment of the present invention;

FIG. 3 shows a side exploded view of the MMC memory card according to one embodiment of the present invention;

FIG. 4 shows an exploded view of the MMC memory card according to the second embodiment of the present invention;

FIG. 5 shows a side exploded view of the MMC memory card according to the second embodiment of the present invention;

FIG. 6 shows an exploded view of the MMC memory card according to the third embodiment of the present invention, and

FIG. 7 shows a side exploded view of the MMC memory card according to the third embodiment of the present invention.

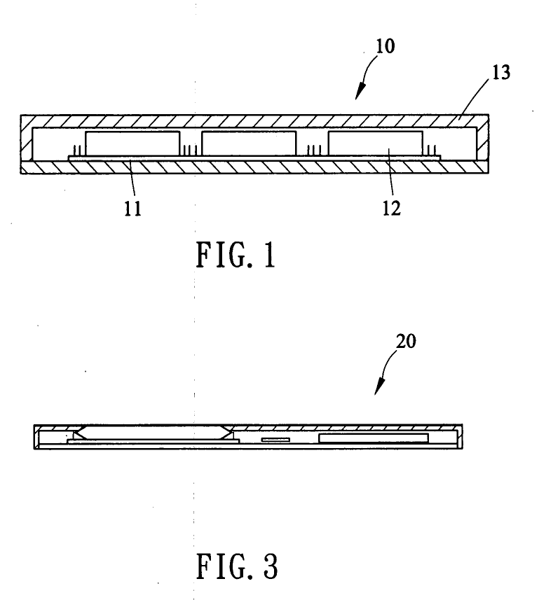

### DETAILED DESCRIPTION OF THE PREFERRED EMBODIMENT

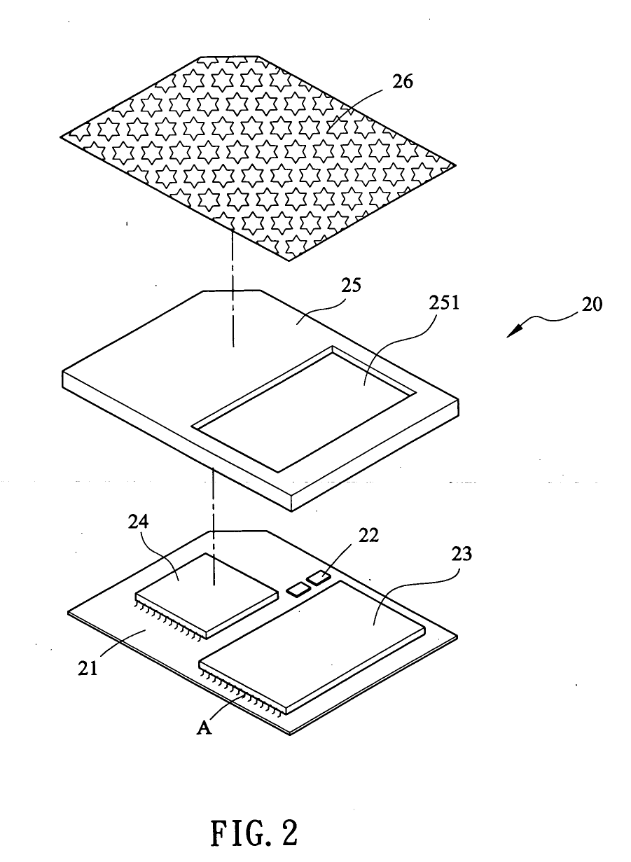

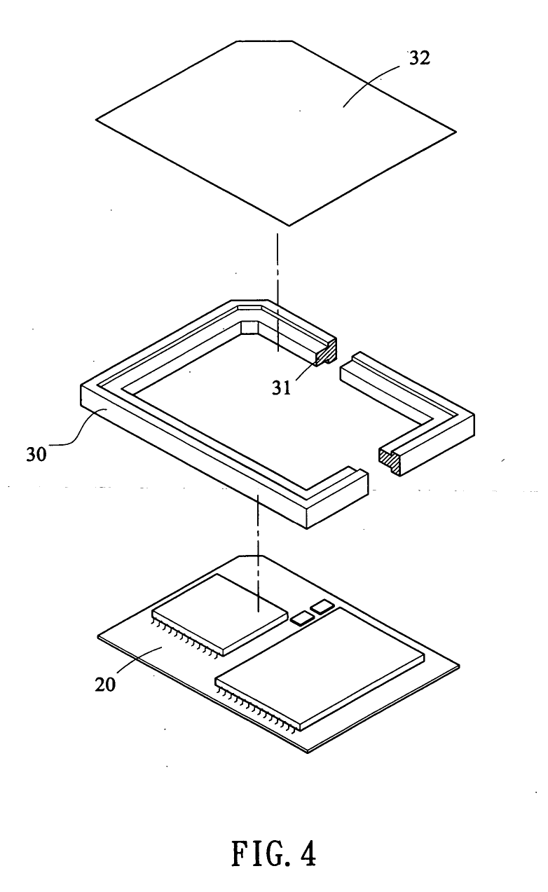

Referring to FIGS. 2 and 3, the MMC memory card 20 of the present invention includes a plurality of passive elements 22 and various ICs installed on a circuit board 21 for forming a required circuit board. Wherein, the various ICs generally comprise a flash memory 23 and a control chip 24. The flash memory manufactured by the TSOP type package is mounted on the circuit board 21 by SMT method, and two pins A are extended respectively from the both sides of the flash memory and connected to the appropriate position of the top surface of the circuit board 21. A molded housing 25 is covered on the circuit board 21 and aligns the window 251 of the top surface of the housing 25 with the top surface of the flash memory 23, so that only the top surface of the flash memory 23 is exposed. Further, a sticker 26 can be stuck on the top surface of the housing 25 to seal and isolate the bare portion of the top surface of the housing 25 so as to form a memory card 20.

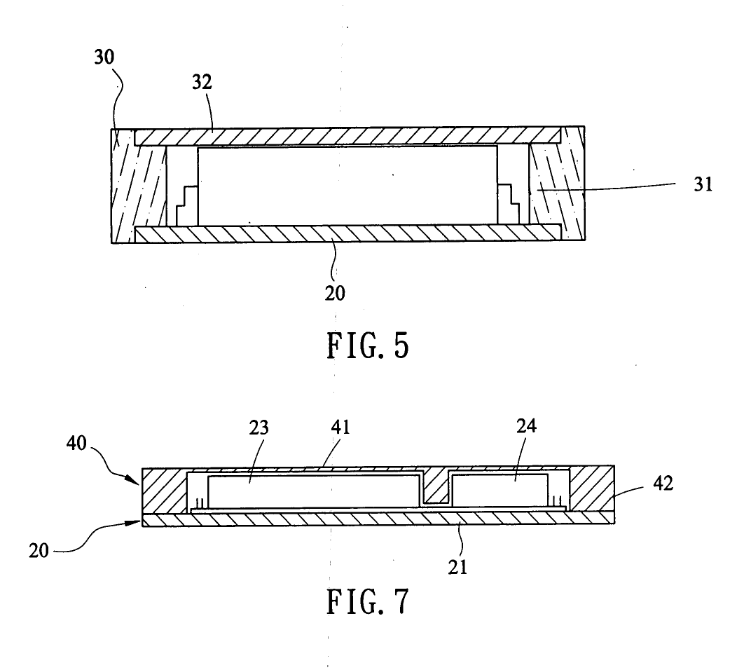

Referring to FIGS. 4 and 5, the circuit board of the MMC memory card 20 of the present invention uses a multiple-layer of plastic housing, the outer frame 30 has a smooth outer edge and a protrusion portion 31 is located at its inner edge. While the circuit board being positioned below the protrusion portion 31 of the outer frame 30, the top edge of the protrusion portion 31 approaches the metal sleeve 32 so as to complete the assembly structure of the memory card 20.

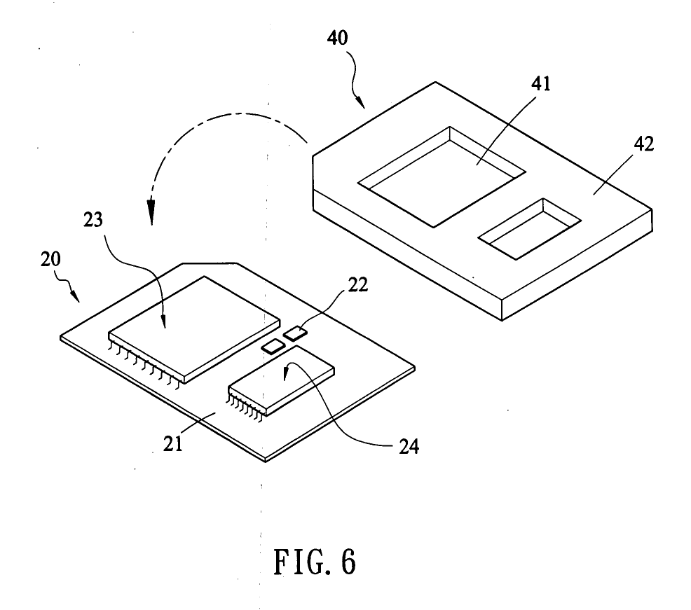

Referring to FIGS. 6 and 7, the circuit board 21 of the MMC memory card 20 of the present invention has been installed a plurality of passive elements 22 and various ICs thereon for forming the required circuit board, and cooperated with the top surface of the housing 40 relative to the thicker IC 23 using extreme thin thickness portion 41 structure, so as to let the IC 23 be positioned at the extreme thin thickness portion 41. The extreme thin thickness portion 41 is combined with the normal thickness portion 42 to form the entire structure such that the IC 23 installed at the extreme thin thickness portion 41 of the housing 40 can be enclosed so as to reach the goal of isolation. Therefore, while assembly the memory card of the present invention, the manufacturer can choose specific IC 23 to cooperate with the extreme thin thickness portion 41 of the housing 40 by using the aforesaid assembly structure according to the cost and convenience of the source, thus can reduce the cost of the IC material and ensure the sealing and assembled quality. Furthermore, While the thicker IC 23 is assembled into the housing 40, two pins A extend respectively from the both sides of the flash memory and are connected to the appropriate position of the top surface of the circuit board 21. a housing 40 is molded over the circuit board 21 and the extreme thin thickness portion 41 of the housing 40 is aligned with the top surface of the flash memory 23, so as to reduce the cost of the IC material and ensure the sealing and assembled quality of the memory card 20.

It should be noted that the MMC memory card cooperated with the aforesaid assembled structure of the present invention doesn't need the traditional molding, gluing, or sealing method to seal the passive elements 22, flash memory 23, control chip 24 etc., so as to reach the goals of sealing and isolating effect, further, it also can reduce the assembly process, reduce the assembly cost and ensure the packaged quality and performance of the memory card.

Furthermore, according to the international standard specification, the total thickness of the memory card should be limited to 1.4 mm. While the memory card 20 of the present invention, the thickness of the circuit board 21 is 0.3 mm, the height between the circuit board 21 and the top surface of the elements is 1.1 mm, and the thickness of the sticker is less than 0.1 mm; therefore, the total thickness of the memory card of the present invention matches the 1.4±0.4 mm specification, so the memory card of the present invention is suitable to the electronic product required memory card in the market.

Furthermore, the memory card of the present invention can appropriately increase the molding thickness of the housing 25 to increase the strength of the memory card 20.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. A MMC memory card with TSOP package comprising:
a circuit board, a plurality of passive elements and ICs installed on said circuit board, a housing covered over and enclosing said circuit board and thereby forming a memory card structure; and
at least one flash memory of said ICs used with a TSOP package and said housing having a space to position said TSOP type flash memory such that enables said TSOP type flash memory to be assembled with said housing.;

2. The MMC memory card used TSOP package as claimed in claim 1, wherein said flash memory has a higher thickness and a plurality of pins distributed on both sides of said flash memory can be extended to the adapted position of the top surface of said circuit board when said flash memory had been mounted on said circuit board.

3. The MMC memory card with TSOP package as claimed in claim 1, wherein said housing is made of plastic material and has a window type position space for positioning said flash memory, and a sticker being attached on a surface formed by said top surface of said flash memory aligning with said window type top surface of said housing to improve covering effect.

4. The MMC memory card with TSOP package as claimed in claim 1, wherein said housing has a position space with a multiple-layer frame for positioning said flash memory, and a metal sheet or plastic sheet covered on said frame so as to protect said circuit board.

5. The MMC memory card with TSOP package as claimed in claim 1, wherein said housing has a position space with thin thickness for positioning said TSOP type flash memory.
